(19) United States
(12) Patent Application Publication
(10) Pub. No.: US 2022/0083261 A1
(43) Pub. Date: Mar. 17, 2022

(54) MEMORY SYSTEM, SEMICONDUCTOR STORAGE DEVICE, AND METHOD FOR READING OUT DATA

(71) Applicant: Kioxia Corporation, Tokyo (JP)

(72) Inventors: Daisuke FUJIWARA, Yokohama (JP); Tomoya SANUKI, Yokkaichi (JP); Toshio FUJISAWA, Yokohama (JP)

(73) Assignee: Kioxia Corporation, Tokyo (JP)

(21) Appl. No.: 17/335,511

(22) Filed: Jun. 1, 2021

(30) Foreign Application Priority Data
Sep. 11, 2020 (JP) 2020-153283

(51) Int. Cl. G06F 3/06

(52) U.S. Cl. CPC G06F 3/0655; G06F 3/0679; G06F 3/0604

(57) ABSTRACT

A memory system of an embodiment includes a NAND memory and a memory controller. The NAND memory includes an encoder configured to convert first data into second data including a plurality of code words generated by dividing the first data into the code words, generate parity data in a horizontal direction of the second data for error check and correct for each code word and encode the first data, and a decoder. A control circuit of the NAND memory controls the decoder to perform hard decision decoding using the parity data in the horizontal direction on readout target data when a readout command is received and outputs the decoded readout target data to the memory controller when the hard decision decoding of the readout target data is successful.

### CROSS-REFERENCE TO RELATED APPLICATIONS

This application is based upon and claims the benefit of priority from the prior Japanese Patent Application No. 2020-153283 filed in Japan on Sep. 11, 2020; the entire contents of which are incorporated herein by reference.

### FIELD

An embodiment described herein relates generally to a memory system, a semiconductor storage device and a method for reading out data.

### BACKGROUND

In a memory system using a non-volatile memory, data is written and read out in a predetermined size. The memory system includes an error check and correct circuit. In the error check and correct circuit, encoding and decoding are performed using an error check and correct code to check and correct an error of the readout data. If data can be randomly read out from the non-volatile memory in a size smaller than the predetermined size, it can be expected to improve readout performance.

However, as a data size becomes smaller, a code rate of data becomes smaller, which results in degradation of transfer efficiency of data and increases cost of the memory system.

Further, in a case where it is necessary to guarantee an error correction rate in requirement specifications at equipment in which the non-volatile memory is used, it is necessary to add a cyclic redundancy check (hereinafter, referred to as CRC) code, or the like, to data. However, addition of the CRC code, or the like, further degrades the code rate.

### BRIEF DESCRIPTION OF THE DRAWINGS

FIG. 1 is a block diagram illustrating a configuration of a memory system according to an embodiment;

FIG. 2 is a block diagram illustrating a detailed configuration of a NAND flash memory according to the embodiment;

FIG. 3 is a circuit diagram for explaining a configuration of a memory cell array in the NAND flash memory according to the embodiment;

FIG. 4 is a diagram for explaining encoding of user data from a host device according to the embodiment;

FIG. 5 is a diagram for explaining a configuration example of a product code frame according to the embodiment;

FIG. 6 is a circuit diagram illustrating configurations of an encoder and a decoder which execute computation using a direct method;

FIG. 7 is a circuit diagram illustrating a configuration of the decoder according to the embodiment;

FIG. 8 is a diagram for explaining a data region to be used by a bit error rate (BER) monitor to generate histogram according to the embodiment;

FIG. 9 is a diagram illustrating an example of the histogram according to the embodiment;

FIG. 10 is a graph for explaining timings for calculating the histogram at the bit error rate (BER) monitor according to the embodiment;

FIG. 11 is a flowchart illustrating an example of flow of operation of error check and correct process in the memory system in a case of random read according to the embodiment;

FIG. 12 is a diagram illustrating that a plurality of pieces of target data are included in sub-page data according to the embodiment;

FIG. 13 is a schematic graph illustrating relationship between a detected raw bit error rate and an uncorrectable bit error rate in hard decision decoding and soft decision decoding according to the embodiment;

FIG. 14 is a block diagram illustrating a configuration of a NAND memory in which a memory cell array unit includes 16 planes according to the embodiment;

FIG. 15 is an assembly diagram illustrating a configuration of the NAND memory according to the embodiment;

FIG. 16 is a diagram illustrating a case where one piece of data to be randomly read exists in each plane of 16 planes according to the embodiment;

FIG. 17 is a diagram illustrating a case where two pieces of data to be randomly read exist in each plane of 16 planes according to the embodiment;

FIG. 18 is a diagram illustrating a case where four pieces of data to be randomly read exist in each plane of 16 planes;

FIG. 19 is a diagram illustrating a configuration of the memory system including a memory controller and a plurality of NAND memories according to the embodiment;

FIG. 20 is a block diagram illustrating a configuration of a memory system according to modification 1 of the embodiment;

FIG. 21 is a diagram for explaining a case where a plurality of pieces of target data in a plurality of word lines are randomly read according to modification 2 of the embodiment; and

FIG. 22 is a graph for explaining timings for calculating histogram for four word lines at a bit error rate (BER) monitor according to the modification 2 of the embodiment.

### DETAILED DESCRIPTION

A memory system of the embodiment includes a non-volatile memory, a controller configured to control write and readout of data in and from the non-volatile memory, an encoder provided in the non-volatile memory and configured to convert first data to be written in the non-volatile memory into second data including a plurality of pieces of unit data generated by dividing the first data into the unit data having a predetermined number of bits, generate first parity data of the second data for error check and correct and second parity data of the second data different from the first parity data for each of the unit data and perform encoding of the first data, a first decoder provided in the non-volatile memory and configured to perform decoding of readout data read out from the non-volatile memory, and a control circuit provided in the non-volatile memory and configured to control the first decoder to perform first decoding using the first parity data on readout target data read out from the non-volatile memory when a readout command is received from the controller, and output the decoded readout target data to the controller when the first decoding of the readout target data is successful.

An embodiment will be described below with reference to the drawings.

### (Configuration)

### (Entire Configuration)

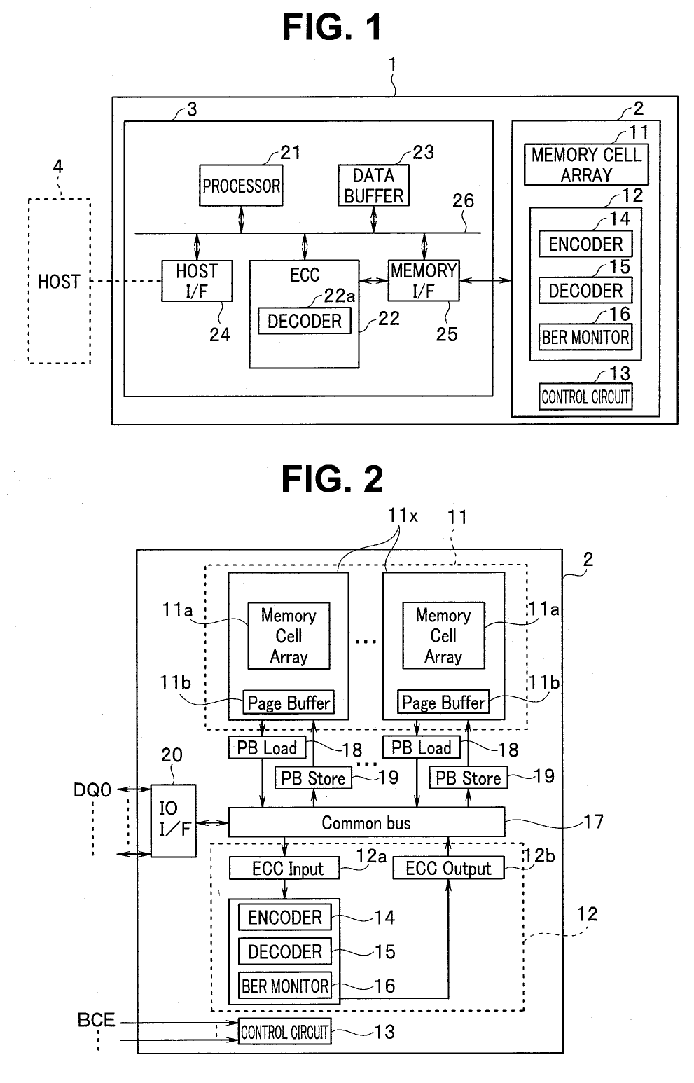

FIG. 1 is a block diagram illustrating a configuration of a memory system according to the present embodiment. A memory system 1 includes a NAND flash memory (hereinafter, referred to as a NAND memory) 2 as a non-volatile memory, and a memory controller 3.

The memory system 1 stores user data in the NAND memory 2 or outputs user data stored in the NAND memory 2 to a host device (hereinafter, also simply referred to as a host) 4 in response to a request from the host 4 indicated with a dotted line. The host 4 is, for example, a personal computer or a smartphone. More specifically, the memory system 1 can write user data in unit of predetermined pages (for example, 16 KB (kilobytes)) in response to a write request from the host and can randomly read out user data of a size smaller than the predetermined pages (for example, 64 B (bytes)) in response to a readout request from the host.

The memory system 1 may be a memory card, or the like, in which the memory controller 3 and the NAND memory 2 are configured as one package or may be an SSD (solid state drive), or the like. FIG. 1 illustrates a state where the memory system 1 is connected to the host 4.

The NAND memory 2 is a semiconductor storage device including a memory cell array unit 11, an error check and correct circuit (hereinafter, referred to as an ECC circuit) 12 and a control circuit 13.

The memory cell array unit 11 includes a plurality of memory cell arrays, and each memory cell array is a non-volatile storage region which can store binary data, or data of four or more values. User data can be stored in the plurality of memory cell arrays of the memory cell array unit 11 in a non-volatile manner. A configuration of the memory cell array unit 11 will be described later.

The ECC circuit 12 includes an encoder 14, a decoder 15, and a bit error rate monitor (hereinafter, referred to as a BER monitor) 16. The ECC circuit 12 is an on-chip ECC circuit to be mounted on the NAND memory 2. In other words, the NAND memory 2 has an error check and correct function.

The encoder 14 of the ECC circuit 12 is a circuit which generates an error check and correct code (that is, parity data) and adds the error check and correct code to the user data when the encoder 14 writes the user data from the memory controller 3 in the memory cell array unit 11. The memory controller 3 writes the user data in the NAND memory 2 in unit of a page having a predetermined size.

The encoder 14 generates parity data in a horizontal direction and in a vertical direction for page data which is reconfigured as a product code frame including a plurality of code words CW (which will be described later) having a predetermined size. The predetermined size is smaller than a size of the page data.

The encoder 14 encodes the product code frame in a horizontal direction and in a vertical direction.

In the present embodiment, the encoder 14 generates parity data in a horizontal direction and in a vertical direction in the product code frame in unit of sub-page data (for example, 4 KB). The predetermined size (for example, 64 B) is smaller than a size of the sub-page data (for example, 4 KB).

Here, the encoder 14 performs encoding using a BCH code which can correct bits equal to or less than four bits.

The decoder 15 checks and corrects an error of the user data read out from the memory cell array unit 11 and outputs the user data. The memory controller 3 specifies a physical address of the NAND memory 2 from an address relating to a readout request and outputs a readout command for random read to the NAND memory 2. The decoder 15 decodes the user data read out in response to the readout command and outputs the user data which has been successfully decoded to the memory controller 3.

The decoder 15 performs hard decision decoding on the basis of hard decision information (that is, hard bits (HB)) which is a binary information expressed with “0” or “1”. As will be described later, the decoder 15 can check and correct an error of data for each code word CW and can output data of the number of corrected bits when the error is checked and corrected, for each code word CW.

More specifically, the decoder 15 decodes the product code frame in a horizontal direction and in a vertical direction, which will be described later. For example, in a case where a size of the page data is approximately 16 KB, the code word CW has a size from 8 B to 10 B. Decoding in the horizontal direction is performed, for example, through computation using a direct method for solving a quartic formula.

The BER monitor 16 is a circuit which has a function of generating histogram of the number of corrected bits when the decoder 15 performs decoding in the horizontal direction. Process content of the BER monitor 16 will be described later.

The control circuit 13 controls operation of respective units of the NAND memory 2 including the error check and correct circuit 12.

The memory controller 3 is a controller which controls write of data in the NAND memory 2 and readout of data from the NAND memory 2. More specifically, the memory controller 3 controls the NAND memory 2 in response to a write request from the host 4. The memory controller 3 writes the user data in the NAND memory 2 in unit of a page having the above-described predetermined size (for example, 16 KB). Further, the memory controller 3 controls the NAND memory 2 in response to a readout request from the host 4. As described above, a size of the user data relating to the readout request from the host 4 is a size of the code word CW which is smaller than the predetermined size of the page data upon writing (for example, 16 KB).

The memory controller 3 includes a processor 21, an ECC circuit 22, a data buffer 23, a host interface circuit (hereinafter, referred to as a host I/F) 24, and a memory interface circuit (hereinafter, referred to as a memory I/F) 25. The processor 21, the ECC circuit 22, the data buffer 23, the host I/F 24 and the memory I/F 25 are connected to each other with an internal bus 26.

The processor 21 overall controls respective units of the memory system 1. The processor 21 performs control in accordance with a request in a case where the processor 21 receives the request from the host 4 via the host I/F 24. For example, the processor 21 instructs the memory IF 25 to write user data in the NAND memory 2 in accordance with the request from the host 4. Further, the processor 21 instructs the memory I/F 25 to read out user data from the NAND memory 2 in accordance with the request from the host 4.

Further, in a case where the processor 21 receives a write request of user data from the host 4, the processor 21 determines a storage region (memory region) on the NAND memory 2 for the user data to be stored in the data buffer 23. In other words, the processor 21 manages a write destination of the user data. Information regarding correspondence relationship between a logical address of the user data received from the host 4 and a physical address indicating the storage region on the NAND memory 2 in which the user data is stored is stored in an address conversion table (which is not illustrated).

Further, in a case where the processor 21 receives a readout request from the host 4, the processor 21 converts the logical address designated by the readout request into a physical address using the above-described address conversion table. The processor 21 instructs the memory I/F 25 to read out data from the physical address.

The ECC circuit 22 decodes data for which decoding has been failed at the NAND memory 2. Thus, the error check and correct circuit 22 includes a decoder 22a. The decoder 22a decodes data through soft decision decoding using a chase decoding method, or the like. Soft decision decoding is process of decoding using information regarding a probability that data obtained through a plurality of times of readout is “0” or “1” (soft decision information (soft bits)).

The data buffer 23 temporarily stores the user data from the host 4 to store the user data in the NAND memory 2. The user data from the host 4 is transferred to the internal bus 26 and temporarily stored in the data buffer 23. Further, the data buffer 23 temporarily stores the user data read out from the NAND memory 2 to transmit the user data to the host 4. The data buffer 23 is a general-purpose memory such as an SRAM (static random access memory) and a DRAM (dynamic random access memory).

The host I/F 24 performs process in accordance with interface standards between the memory system 1 and the host 4. The host I/F 24 outputs the request and the user data received from the host 4 to the internal bus 26. The host I/F 24 transmits the user data read out from the NAND memory 2, a response from the processor 21, or the like, to the host 4.

The memory I/F 25 performs process regarding write of data in the NAND memory 2 and readout of data from the NAND memory 2 under control of the processor 21.

### (Configuration of Non-Volatile Memory)

FIG. 2 is a block diagram illustrating a detailed configuration of the NAND memory 2. As described above, the NAND memory 2 includes the memory cell array unit 11, the ECC circuit 12, and the control circuit 13. In FIG. 2, the memory cell array unit 11 includes a plurality of planes 11x. Each plane 11x includes a memory cell array 11a, a row decoder (not illustrated), and a column decoder (not illustrated). The column decoder includes a page buffer 11b which stores page data Pd. The page buffer 11b stores the page data Pd upon writing and readout of data. The ECC circuit 12 and the plurality of planes 11x are connected via a common bus 17.

Note that while the memory cell array unit 11 includes a plurality of planes 11x here, the memory cell array unit 11 may include one plane.

The NAND memory 2 includes a plurality of page buffer load circuits 18 and a plurality of page buffer store circuits 19 provided between the plurality of planes 11x and the common bus 17. Each page buffer load circuit 18 loads data stored in the page buffer 11b and outputs the data to the common bus 17. Each page buffer store circuit 19 stores data from the common bus 17 in the page buffer 11b.

The ECC circuit 12 includes an ECC input circuit 12a which receives input of data and an ECC output circuit 12b which outputs data in addition to the encoder 14, the decoder 15 and the BER monitor 16 described above. The ECC input circuit 12a is a circuit which receives input data to be processed at the ECC circuit 12 from the common bus 17 and outputs the data to the encoder 14, or the like. The ECC output circuit 12b is a circuit which receives process result data (encoded data or decoded data) of the ECC circuit 12 and outputs the process result data to the common bus 17. Configurations of the encoder 14 and the decoder 15 will be described later.

A bus width of the common bus 17 is the same as, for example, the number of bits of data obtained by combining the code word CW and a horizontal parity (pbh) (this data will be hereinafter referred to as code word unit data CWU), and enables high-speed decoding.

Further, the NAND memory 2 includes an input/output interface (hereinafter, abbreviated as an input/output I/F) 20 for transmitting and receiving data (address and data) between the NAND memory 2 and the memory controller 3. The input/output I/F 20 is connected to the common bus 17. The input/output I/F 20 is connected to the memory I/F 25 of the memory controller 3 with a plurality of data input/output lines.

The input/output I/F 20 is connected to data input/output lines DQ0 to DQ7. The input/output I/F 20 receives an address and data from the data input/output lines DQ0 to DQ7 and outputs the address and the data to the control circuit 13. The control circuit 13 outputs readout data and various kinds of data from the data input/output lines DQ0 to DQ7 via the input/output I/F 20.

The control circuit 13 receives various kinds of control signals via a control signal input interface (not illustrated). The various kinds of control signals include a chip enable signal BCE, a command latch enable signal CLE, an address latch enable signal ALE, a write enable signal BWE, read enable signals RE and BRE (complementary signal of RE), a write protect signal BWP and data strobe signals DQS and BDQS (complementary signal of DQS).

The chip enable signal BCE is used as a selection signal of the NAND memory 2. The command latch enable signal CLE is a signal to be used to import an operation command to a register (not illustrated). The address latch enable signal ALE is a signal to be used to import address information or input data to a built-in register (not illustrated). The write enable signal BWE is a signal for importing a command, an address and data on the input/output I/F 20 to the NAND memory 2. The read enable signals RE and BRE are signals to be used to output data from the input/output I/F 20 in series. The write protect signal BWP is used to protect data from unexpected erasure or writing in a case where an input signal is indeterminate upon power-on, power-off, or the like, of the NAND memory 2.

Note that while both an address and data are transmitted and received between the memory I/F 25 and the input/output I/F 20, the address and the data may be transmitted and received using a common signal line or the address and the data may be transmitted and received respectively using a signal line for address and a signal line for data. By transmitting and receiving the address and the data respectively using the signal line for address and the signal line for data, it is possible to reduce latency in data transfer.

### (Configuration of Memory Cell Array)

A configuration of a memory cell array of each plane will be described next.

In each plane 11x, data is written in a predetermined size called page, and data is erased in unit of data called block. A plurality of memory cells to be connected to the same word line of the memory cell array 11a will be referred to as a memory cell group. In a case where the memory cell is a single-level cell (SLC), one memory cell group corresponds to one page. In a case where the memory cell is a multi-level cell (MLC), one memory cell group corresponds to a plurality of pages. Further, each memory cell is connected to a word line and is also connected to a bit line. Thus, each memory cell can be identified with an address which identifies a word line and an address which identifies a bit line.

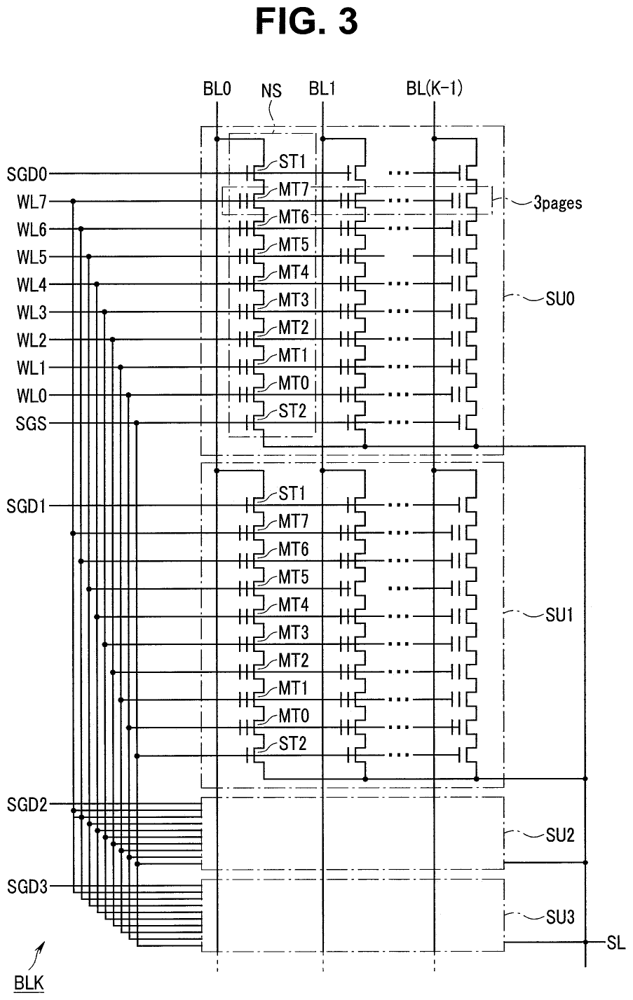

FIG. 3 is a circuit diagram illustrating a configuration of the memory cell array 11a according to the present embodiment. In the present example, as illustrated, one block BLK includes, for example, four string units SU (SU0 to SU3). Further, each string unit SU includes a plurality of NAND strings NS.

Each NAND string NS includes, for example, eight memory cell transistors MT (MT0 to MT7) and two select transistors ST1 and ST2. Each memory cell transistor MT includes a control gate and a charge accumulation layer, and stores data in a non-volatile manner. Further, a plurality of (for example, eight) memory cell transistors MT are connected in series between a source of the select transistor ST1 and a drain of the select transistor ST2. FIG. 3 illustrates an example where one string unit SU includes eight word lines WL to simplify the explanation.

Gates of the select transistors ST1 of the respective string units SU0 to SU3 are respectively connected to select gate lines SGD0 to SGD3. In contrast, gates of select transistors ST2 of the respective string units SU0 to SU3 are, for example, commonly connected to a select gate line SGS. Of course, the gates of the select transistors ST2 of the respective string units SU0 to SU3 may be connected to select gate lines SGS0 to SGS3 which are different for each string unit. Further, control gates of the memory cell transistors MT0 to MT7 within the same block BLK are respectively commonly connected to word lines WL0 to WL7.

Further, drains of the select transistors ST1 of a plurality of NAND strings NS in the same column within the memory cell array 11a are commonly connected to bit lines BL (BL0 to BL(K−1), where K is a natural number equal to or greater than 2). In other words, the bit lines BL commonly connect a plurality of NAND strings NS among a plurality of blocks BLK. Further, sources of a plurality of select transistors ST2 are commonly connected to a source line SL.

In other words, the memory cell array 11a is an aggregate of a plurality of blocks BLK to which respective bit lines BL are commonly connected. Further, each block BLK includes a plurality of string units SU commonly connected to respective word lines WL. The respective string units SU are connected to a plurality of bit lines BL which are different from each other and include a plurality of NAND strings NS connected to the same select gate line SGD.

Returning to FIG. 1, the NAND memory 2 further includes a driver circuit, an address register, a command register, or the like, which are not illustrated. The control circuit 13 which is a sequencer performs write process of data in each plane 11x and readout process of data from each plane 11x by controlling the whole operation of the NAND memory 2 on the basis of the command stored in the command register.

Here, one memory cell transistor MT can store one-bit data. In other words, the NAND memory 2 is a semiconductor storage device employing a so-called SLC (single-level cell) scheme.

Note that one memory cell transistor MT may be able to store, for example, multiple-valued data. For example, in a case where one memory cell transistor MT can store three-bit data, the NAND memory 2 is a semiconductor storage device employing a so-called TLC (triple-level cell) scheme. Bits of the three-bit data will be respectively referred to as a lower bit, a middle bit and an upper bit from a lower-order bit. Further, an aggregate of lower bits stored by a plurality of memory cell transistors MT connected to the same word line WL in one string unit will be referred to as a lower page, an aggregate of middle bits will be referred to as a middle page, and an aggregate of upper bits will be referred to as an upper page. A plurality of memory cell transistors MT connected to one word line in one string configure one page unit which stores lower, middle and upper bits. In other words, as indicated with a dashed-dotted line in FIG. 3, three pages are allocated to each page unit. Data is written in unit of the page unit, and data is read out for each page.

In a case where one memory cell transistor MT can store multiple-valued data, data is written through so-called low-speed writing (that is, high-reliability writing).

### (Encoding)

The user data which is data to be written is encoded by the encoder 14 and stored in the NAND memory 2. The user data is encoded by a product code frame.

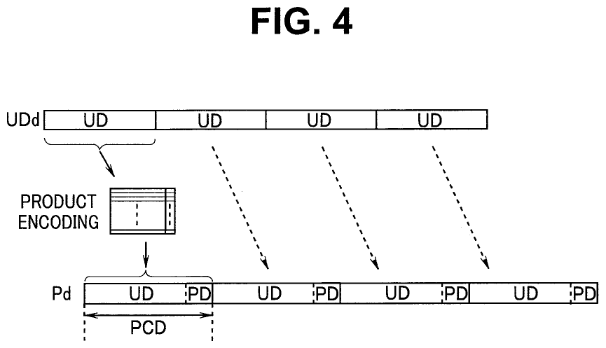

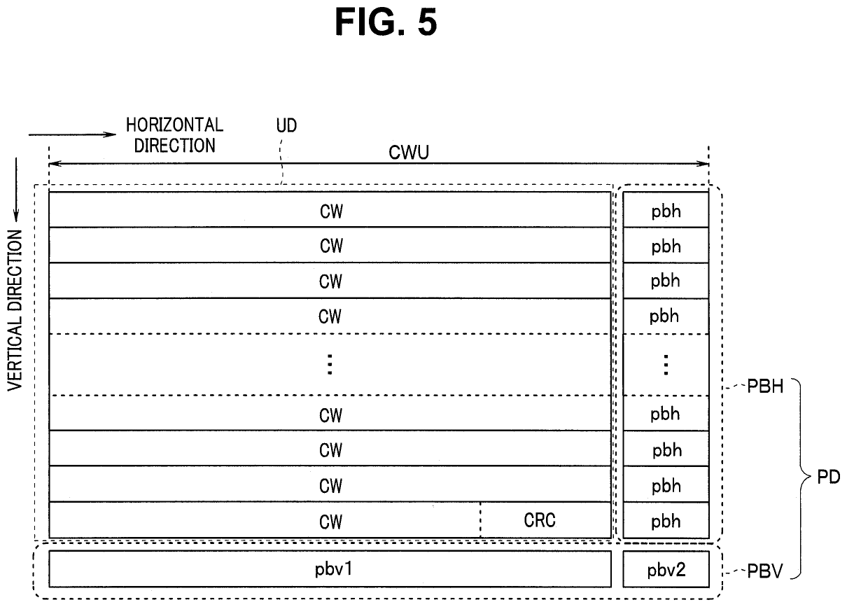

FIG. 4 is a diagram for explaining encoding of the user data from the host 4. FIG. 5 is a diagram for explaining a configuration example of the product code frame.

As illustrated in FIG. 4, user data UDd which is data to be written at one time is divided into four pieces of sub-user data UD. Four pieces of sub-user data UD correspond to four pieces of sub-page data PCD which will be described later. Each piece of sub-user data UD is reconfigured by the control circuit 13 as a product code frame including data having a plurality of rows and a plurality of columns.

As illustrated in FIG. 5, the product code frame is a data frame which includes a plurality of rows of data (hereinafter, referred to as code words) CW of a predetermined size. Each code word CW has a predetermined data size within a range from, for example, 8 B (64 bits) to 100 B (800 bits). Here, the number of bits of the code word CW is 64 B. The product code frame includes a parity bit portion PBH in a horizontal direction and a parity bit portion PBV in a vertical direction.

Note that as illustrated in FIG. 5, each piece of sub-user data UD includes a code portion for CRC.

The parity bit portion PBH is a plurality of parity bits pbh added in a horizontal direction for each code word CW. The parity bits pbh are parity bits in a horizontal direction. Data obtained by combining one code word CW and the parity bits pbh is code word unit data CWU. The encoder 14 generates the parity bits pbh in the horizontal direction for each code word CW on the basis of a BCH (Bose-Chaudhuri-Hocquenghem) coding scheme. Here, encoding is performed using a BCH code which can correct bits equal to or less than four bits for the code word CW of 64 B (that is, 512 bits), and the parity bits pbh are added to the code word CW.

For example, in a case where encoding is performed using a BCH code which can correct bits equal to or less than four bits, in a case where a code word CW length is 64 B, a code rate of the user data is 0.86, and in a case where the code word CW length is 48 B, a code rate of the user data is 0.89.

The parity bit portion PBV is parity bits in a vertical direction added for a plurality of pieces of code word unit data CWU. The parity bit portion PBV includes parity bits pbv1 corresponding to a plurality of code words CW and parity bits pbv2 corresponding to the parity bit portion PBH.

The parity bits pbv1 and pbv2 in the vertical direction are generated through XOR (exclusive OR) computation in the vertical direction. Note that the parity bits in the vertical direction may be generated on the basis of other coding schemes such as a Reed-Solomon coding scheme and a BCH coding scheme.

As illustrated in FIG. 4, the user data UDd (for example, 16 KB) is divided into four pieces of sub-user data UD. Parity data PD based on the product code frame is generated for each piece of sub-user data UD (for example, 4 KB). Thus, the encoder 14 generates four pieces of sub-page data PCD including the sub-user data UD and the parity data PD. Each piece of sub-page data PCD is a product code ECC frame. The product code ECC frame is an ECC process unit in unit of the product code frame. The control circuit 13 writes the generated four pieces of sub-page data PCD in word lines WL of a physical address of the designated plane 11x.

Note that while FIG. 4 illustrates a case where the page data Pd has a data structure having two data fields of sub-user data UD from the memory controller 3 and parity data PD in each piece of sub-page data PCD based on the product code frame, the page data Pd may have a data structure where a plurality of pieces of data to which the parity bits pbh are added for each code word CW illustrated in FIG. 5 are coupled in series and the parity bit portion PBV is added at the end.

Data included in the parity bit portion PBH in the horizontal direction and the parity bit portion PBV in the vertical direction configures the parity data PD.

As described above, the encoder 14 creates the product code frame for each piece of sub-user data UD and calculates parity data in the horizontal direction and in the vertical direction.

As illustrated in FIG. 4, the page data Pd includes user data UDd and the parity data PD in the horizontal direction and in the vertical direction. The respective code words CW and the parity data PD corresponding to the code words are arranged in association with locations determined in advance in the page data Pd.

As described above, the control circuit 13 is provided at the NAND memory 2 and divides data to be written in the NAND memory 2 into unit data (in the above-described example, the code words CW) having a predetermined number of bits.

The encoder 14 converts the data into the product code frame including a plurality of pieces of unit data (CW). Then, the encoder 14 generates first parity data in the horizontal direction of the product code frame for error check and correct and second parity data in the vertical direction of the product code frame for each piece of unit data (code word CW) and encodes the data to be written.

The page data Pd is output to the memory cell array unit 11 via the common bus 17.

### (Decoding)

The decoder 15 decodes the encoded user data. In other words, the decoder 15 is provided at the NAND memory 2 and decodes the readout data read out from a plurality of planes 11x of the NAND memory 2. As described above, the decoder 15 performs hard decision decoding on the basis of hard decision information which is binary information expressed with “0” or “1”.

The decoder 15 includes a first decoding process unit configured to correct bits equal to or less than four bits of the code word CW in the horizontal direction using a direct method, and a second decoding process unit configured to perform decoding process of the product code frame in the vertical direction. The decoder 15 corrects bits equal to or less than four bits using the direct method, so that the decoder 15 can perform decoding process in the horizontal direction at high speed.

The first decoding process unit of the decoder 15 performs decoding of the code word CW in the horizontal direction through computation using the direct method. The computation using the direct method is described in, for example, “Hybrid methods for finding roots of a polynomial with application to BCH decoding”, R. T. Chien, B. D. Cunningham, I. B. Oldham, IEEE Transactions on Information Theory, vol. 15, No. 2, pp. 329-335, 1969.

Note that the second decoding process unit of the decoder 15 decodes the product code frame in the vertical direction.

The decoder 15 outputs data of the number of corrected bits when error check and correction is performed in decoding of each code word CW in the horizontal direction. The data of the number of corrected bits is used to generate histogram at the BER monitor 16 which will be described later.

Configurations of the encoder 14 and the decoder 15 will be described next. While encoding process and decoding process in the horizontal direction regarding the direct method will be described, encoding process and decoding process in the vertical direction are performed through XOR computation, or the like, and thus, description will be omitted.

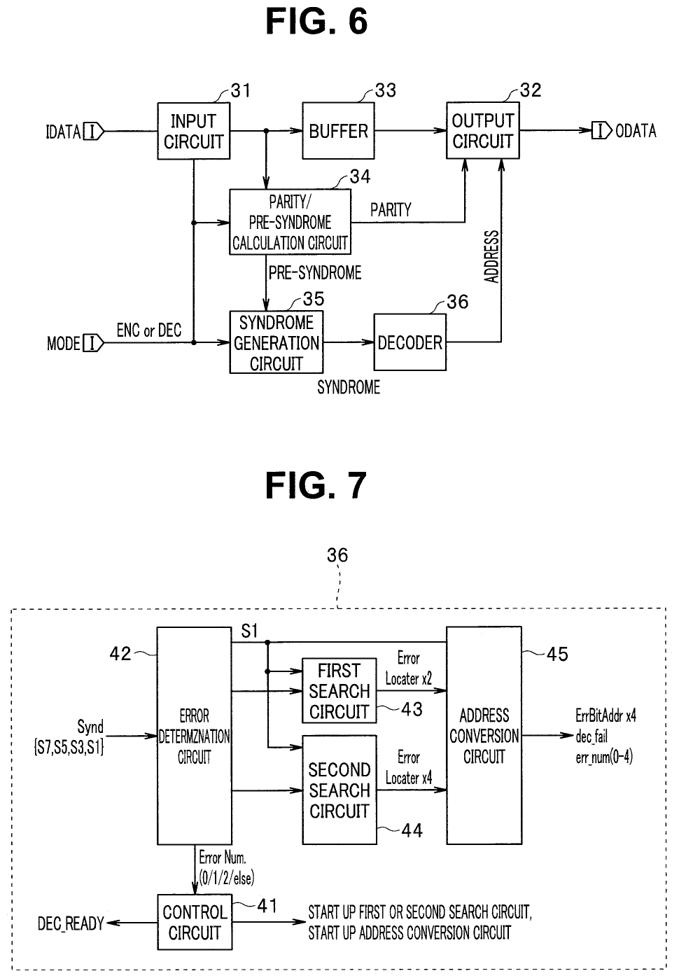

FIG. 6 is a circuit diagram illustrating the configurations of the encoder 14 and the decoder 15 which execute computation using the direct method. The encoder 14 and the decoder 15 are implemented with a circuit 30 illustrated in FIG. 6. The circuit 30 includes an input circuit 31, an output circuit 32, a buffer 33, a parity/pre-syndrome calculation circuit 34, a syndrome generation circuit 35, and a decoder 36.

Input data IDATA and mode data MODE are input to the circuit 30. The circuit 30 outputs encoded data or decoded data. The mode data MODE indicates an encode mode for causing the circuit 30 to operate as the encoder 14 and a decode mode for causing the circuit 30 to operate as the decoder 15. The mode data MODE is provided from the control circuit 13.

The input circuit 31 is a circuit which imports the input data IDATA. During the encode mode, the input data IDATA is data of the code word CW. During the decode mode, the input data IDATA is encoded data (code word unit data CWU) including the code word CW to which the horizontal direction parity is added.

The output circuit 32 is a circuit which outputs encoded data or decoded data as output data ODATA. During the decode mode, the output data ODATA is data of the code word CW. During the encode mode, the output data ODATA is encoded data including the code word CW to which the horizontal direction parity is added.

The buffer 33 is a circuit which temporarily stores the input data IDATA.

The parity/pre-syndrome calculation circuit 34 calculates and outputs a parity in a case of encoding of the input data IDATA (for example, the code word CW of 64 B) and calculates and outputs a pre-syndrome in a case of decoding of the input data IDATA.

More specifically, in a case where the operation mode is the encode mode, the parity/pre-syndrome calculation circuit 34 generates parity bits. The generated parity bits are output to the output circuit 32. The output circuit 32 outputs the encoded data as the output data ODATA. The encoded data is code word unit data CWU in which the parity bits are added to the input data stored in the buffer 33.

In a case where the operation mode is the decode mode, the parity/pre-syndrome calculation circuit 34 calculates a pre-syndrome and outputs the pre-syndrome to the syndrome generation circuit 35.

In a case where the operation mode is the decode mode, the syndrome generation circuit 35 generates a syndrome on the basis of the pre-syndrome. Here, bits equal to or less than four bits are corrected, and thus, the syndrome is S1, S3, S5 and S7.

The decoder 36 is a circuit which outputs an address indicating an error bit location or a failure in correction on the basis of the generated syndrome.

FIG. 7 is a circuit diagram illustrating a configuration of the decoder 36. The decoder 36 includes a control circuit 41, an error determination circuit 42, a first search circuit 43, a second search circuit 44, and an address conversion circuit 45.

The decoder 36 receives input of the syndrome and outputs address information regarding an error location.

The control circuit 41 controls the whole operation of the decoder 36.

The error determination circuit 42 receives input of the syndrome and determines the number of corrected bits of the error. The error determination circuit 42 also calculates various kinds of interim information for searching a bit error location. The error determination circuit 42 outputs the syndrome and the interim information to the first search circuit 43 and the second search circuit 44. The error determination circuit 42 outputs data of the number of corrected bits to the control circuit 41.

The data of the number of corrected bits is used at the BER monitor 16.

The control circuit 41 starts up the first search circuit 43 or the second search circuit 44 on the basis of the number of corrected bits. In a case where the number of corrected bits is 1 or 2, the control circuit 41 starts up the first search circuit 43 and does not start up the second search circuit 44. In a case where the number of corrected bits is 3 or 4, the control circuit 41 does not start up the first search circuit 43 and starts up the second search circuit 44.

The first search circuit 43 receives input of the syndrome S1 and the interim information. The first search circuit 43 searches locations of errors of one or two bits.

The second search circuit 44 receives input of the syndrome S1 and the interim information. The second search circuit 44 searches locations of errors of three or four bits.

In other words, the decoder 15 includes the error determination circuit 42 which determines the number of errors, the first search circuit 43 which searches error bit locations in a first number of errors, and the second search circuit 44 which searches error bit locations in a second number of errors different from the first number of errors.

Further, the control circuit 41 instructs the address conversion circuit 45 on the basis of the number of corrected bits. In a case where the number of corrected bits is one or two, the control circuit 41 instructs the address conversion circuit 45 to receive output of the first search circuit 43. In a case where the number of corrected bits is three or four, the control circuit 41 instructs the address conversion circuit 45 to receive output of the second search circuit 44.

The address conversion circuit 45 converts the error location information from the first search circuit 43 or the second search circuit 44 into address information regarding the error bit locations in the input data IDATA. The address conversion circuit 45 also outputs information regarding the number of corrected bits and information regarding a failure in decoding.

In a case where the control circuit 41 receives information indicating that the number of corrected bits from the error determination circuit 42 is 0, the control circuit 41 outputs ready state information (DEC_READY). The control circuit 41 can stop operation of the first search circuit 43 and the second search circuit 44 on the basis of the ready state information (DEC_READY). As a result, a state occurs where neither the first search circuit 43 nor the second search circuit 44 consumes power, so that it is possible to reduce current efficiency.

As described above, the first search circuit 43 and the second search circuit 44 are controlled so that in a case where the number of errors determined by the error determination circuit 42 is the first number of errors, the first search circuit 43 operates, and the second search circuit 44 does not operate, in a case where the number of errors determined by the error determination circuit 42 is the second number of errors, the first search circuit 43 does not operate, and the second search circuit 44 operates, and in a case where the number of errors determined by the error determination circuit 42 is 0, neither the first search circuit 43 nor the second search circuit 44 operates.

In the present embodiment, the memory controller 3 can perform random read in accordance with the data readout request from the host 4. In the present specification, random read is process of reading out data of part of one page, for example, in unit of several bytes to 100 bytes. In other words, random read refers to readout of data of a small data size (for example 64 B) within one page or within one sub-page.

### (BER Monitoring)

The BER monitor 16 is a circuit which generates histogram of the number of corrected bits determined for data which is part of the page data Pd including data to be read out in random read. Here, if the page data Pd is approximately 16 KB, part of the page data Pd is 512 B at the head.

When the control circuit 13 receives a readout command from the memory controller 3, the control circuit 13 supplies data in a region determined in advance in the page data Pd or the sub-page data PCD including an address designated in the command to the decoder 15.

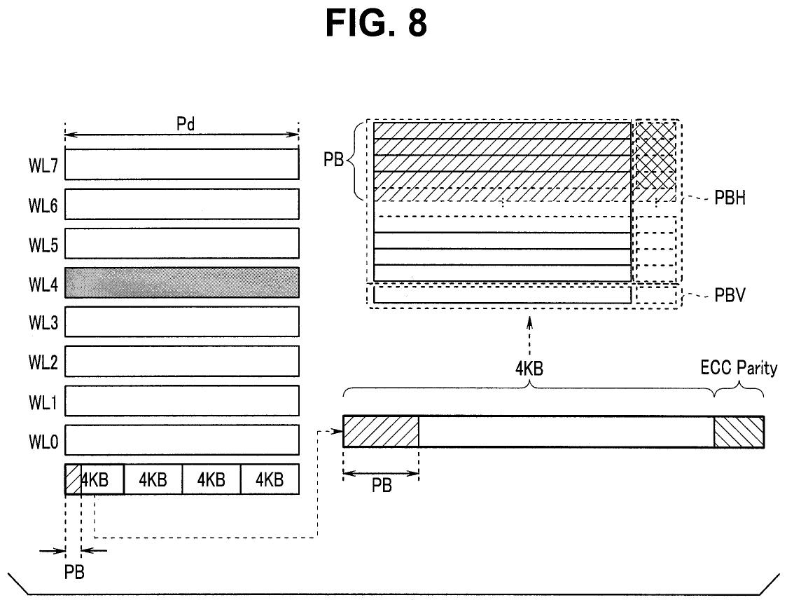

FIG. 8 is a diagram for explaining a data region to be used by the BER monitor 16 to generate histogram. A plurality of pieces of page data Pd are stored in the NAND memory 2. When the page data Pd (for example, a word line WL4 in FIG. 8) including a target address of random read is read out, data in a predetermined region PB in the page data Pd or the sub-page data PCD is supplied to the decoder 15 as a BER monitor region. Here, as illustrated in FIG. 8, the data in the predetermined region (hereinafter, referred to as a BER monitor region) PB is 512 B data at the head of the page data Pd. In other words, the data in the BER monitor region PB is part of data which is a unit of readout of data from the NAND memory 2.

The control circuit 13 supplies a plurality of code words CW in the BER monitor region PB to the decoder 15. The decoder 15 decodes the respective input code words CW in the BER monitor region PB using the parity bits pbh which are ECC parities and outputs data of the number of corrected bits. As described above, the decoder 15 outputs the data of the number of corrected bits obtained in decoding process. Thus, the decoder 15 outputs data of the number of corrected bits concerning a plurality of input code words CW included in the BER monitor region PB.

The BER monitor 16 can obtain histogram data of the number of corrected bits by processing data of the number of corrected bits of the plurality of code words CW determined at the decoder 15, for example, processing the data by a pipeline processing circuit. Thus, the control circuit 13 generates histogram of the number of corrected bits on the basis of the data of the number of corrected bits output from the decoder 15.

As described above, data of part of the storage region of the memory cell array unit 11 including the readout target data TD is decoded by the decoder 15 for each code word CW as unit data. The BER monitor 16 provided at the NAND memory 2 calculates a bit error rate (BER) based on the number of corrected bits for each piece of unit data and monitors the bit error rate (BER).

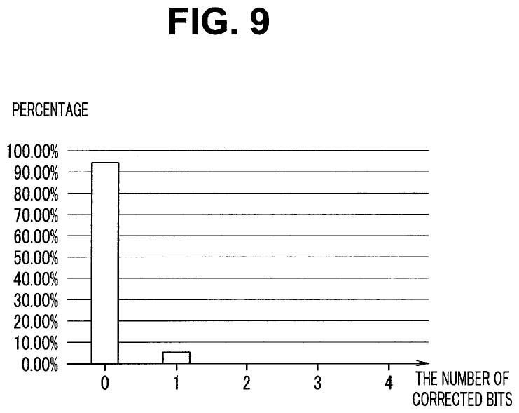

FIG. 9 is a diagram illustrating an example of the histogram. The control circuit 13 generates histogram for each number of corrected bits as illustrated in FIG. 9 from the data of the number of corrected bits output from the decoder 15. FIG. 9 illustrates an example where the BER monitor region PB includes many code words CW for which the number of corrected bits is “0”, a few code words CW for which the number of corrected bits is “1” and no code word CW for which the number of corrected bits is equal to or larger than “2”.

As illustrated in FIG. 9, even if percentage of the number of corrected bits being “0” is high and percentage of the number of corrected bits being “1” is low, in a case where percentage of the number of corrected bits being equal to or larger than “2” is “0”, it can be considered that an error correction rate upon decoding of data to be randomly read included in the page data Pd is low. Inversely, in a case where percentage of the number of corrected bits being equal to or larger than “2” is higher than predetermined percentage, it can be considered that an error correction rate upon decoding of data to be randomly read included in the page data Pd is likely to be not low. The control circuit 13 can determine whether or not an error correction rate upon decoding of data to be randomly read included in the page data Pd or the sub-page data PCD is low from the data of the histogram generated by the BER monitor 16.

For example, in a case where the percentage of the number of corrected bits being equal to or larger than “2” is 0%, and the percentage of the number of corrected bits being “1” is equal to or less than 10%, and the rest corresponds to the number of corrected bits being “0”, the control circuit 13 determines that an error correction rate upon decoding of data to be randomly read included in the page data Pd or the sub-page data PCD is low, and in other cases, the control circuit 13 determines that the error correction rate upon decoding of the data to be randomly read included in the page data Pd or the sub-page data PCD is not low.

Here, the control circuit 13 compares a predetermined threshold for percentage with respect to the whole for each number of corrected bits with percentage of each detected number of corrected bits with respect to the whole and determines whether or not an error correction rate upon decoding of the data to be randomly read included in the page data Pd or the sub-page data PCD is low.

Note that whether or not the error correction rate upon decoding is low may be determined through comparison between a value of each detected number of corrected bits and a predetermined value (threshold).

In the present embodiment, at the NAND memory 2, the BER monitor 16 calculates the histogram data (data of the number of corrected bits of the page data Pd or the sub-page data PCD including the data to be randomly read). In a case where it is determined that the error correction rate upon decoding is low on the basis of the histogram data, the NAND memory 2 outputs data of one or more code words CW as is to the memory controller 3 as the data to be randomly read in a case where the encoder 14 has been successful in horizontal decoding through hard decision decoding (hereinafter, also referred to as horizontal HB decoding).

Further, as will be described later, in a case where the horizontal HB decoding has been failed, the NAND memory 2 decodes the page data Pd or the sub-page data PCD including the data to be randomly read through hard decision decoding of the product code frame in the vertical direction. In a case where vertical decoding through hard decision decoding (hereinafter, also referred to as vertical HB decoding) has been successful, the NAND memory 2 outputs the page data Pd or the sub-page data PCD and the decoded data to the memory controller 3.

Further, in a case where the vertical HB decoding of the product code frame has also been failed, the NAND memory 2 outputs the data of the page data Pd or the sub-page data PCD including the data to be randomly read to the memory controller 3, and the memory controller 3 performs horizontal decoding through soft decision decoding (hereinafter, also referred to as horizontal SB decoding) of the product code frame.

Further, in a case where the soft decision decoding in the horizontal direction has also been failed at the memory controller 3, the memory controller 3 performs vertical decoding through soft decision decoding (hereinafter, also referred to as vertical SB decoding) of the product code frame.

BER calculation by the BER monitor 16 and random read process may be sequentially executed or may be executed in parallel.

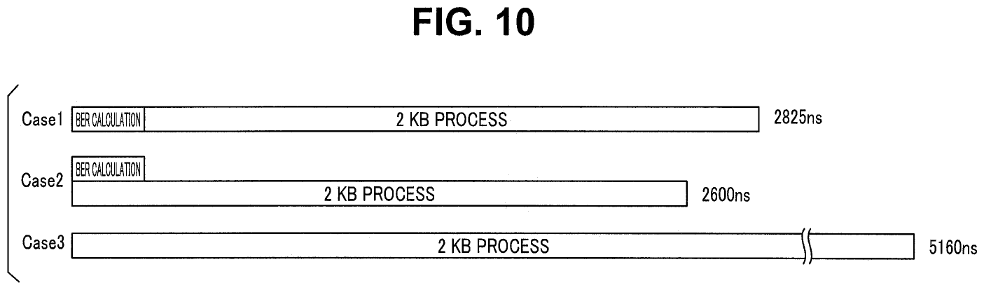

FIG. 10 is a graph for explaining timings for calculating histogram by the BER monitor 16. FIG. 10 is a diagram illustrating timings for reading out data of 12.5% (2 KB) among data in one page (16 KB). FIG. 10 illustrates timing charts of case 1, case 2 and case 3. Case 1 is a case where histogram calculation in the present embodiment and random read are performed in series. Case 2 is a case where histogram calculation in the present embodiment and random read are performed in parallel. Case 3 is a case where the memory controller 3 decodes data subjected to BCH encoding for each 64 B without product encoding being performed and reads out data of 2 KB.

In case 1, histogram of data of the number of corrected bits is calculated using a plurality of code words CW (in a case of 24 B) of the BER monitor region PB within the page data Pd, and then, data of 2 KB is read out. In simulation calculation by the applicant under predetermined conditions, it takes 2825 ns (nanoseconds) to read out data of 2 KB in one page.

In case 2, histogram of the data of the number of corrected bits is calculated using a plurality of code words CW (in a case of 24 B) of the BER monitor region PB within the page data Pd in parallel to readout of data of 2 KB. In simulation calculation by the applicant under predetermined conditions, it takes 2600 ns (nanoseconds) to read out data of 2 KB in one page.

In case 3, it takes 5160 ns (nanoseconds) to read out data of 2 KB in one page in simulation calculation by the applicant under predetermined conditions.

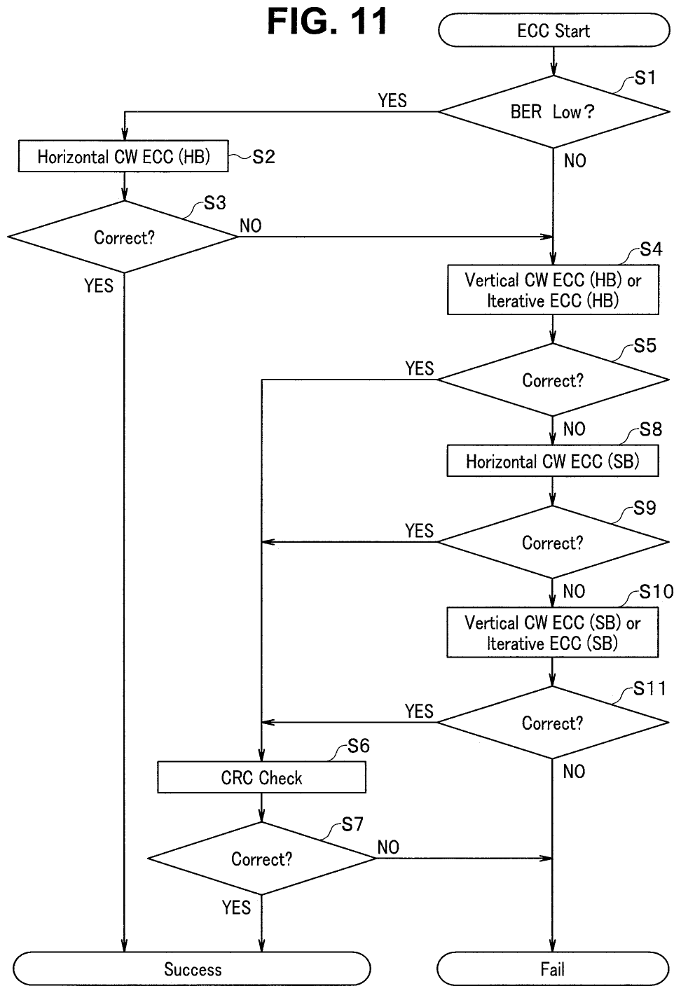

FIG. 11 is a flowchart illustrating an example of flow of operation of error check and correct process in the memory system 1 in a case of random read.

When the processor 21 of the memory controller 3 receives a readout request of data from the host 4, the processor 21 outputs a physical address (physical address of a storage region including target data) converted from a logical address of data regarding the readout request (that is, target data) and a readout command to the NAND memory 2. A case will be described here where a plurality of pieces of target data in one piece of sub-page data PCD in one piece of page data Pd are read out.

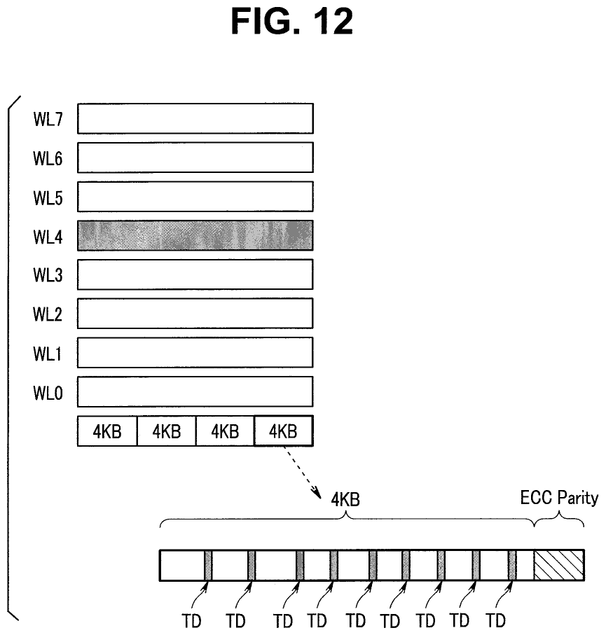

FIG. 12 is a diagram illustrating that the sub-page data PCD includes a plurality of pieces of target data TD. As illustrated in FIG. 12, a plurality of pieces of target data TD exist in the sub-page data PCD (4 KB).

The control circuit 13 specifies pages of a plurality of physical addresses and reads out page data Pd of the physical addresses from the memory cell array unit 11. The control circuit 13 instructs the BER monitor 16 to generate histogram of the number of corrected bits in the BER monitor region PB of the readout page data Pd. When the control circuit 13 receives the histogram data from the BER monitor 16, process in FIG. 11 is executed.

The control circuit 13 determines whether a bit error rate (BER) of the page data Pd including a plurality of pieces of target data TD is lower than predetermined percentage from the histogram data from the BER monitor 16 (step (hereinafter, abbreviated as S) 1).

As described above, for example, in a case where percentage of the number of corrected bits being equal to or larger than “2” is 0%, percentage of the number of corrected bits being “1” is equal to or less than 10%, and the rest corresponds to the number of corrected bits being “0”, the control circuit 13 determines that the bit error rate (BER) of the page data Pd including the target data TD is low. In other cases, the control circuit 13 determines that the bit error rate (BER) of the page data Pd including the target data TD is not low.

In a case where the bit error rate is lower than predetermined percentage (S1: YES), the control circuit 13 executes hard decision decoding in the horizontal direction on each code word CW including data of the addresses of the target data TD from the product code frame of the sub-page data PCD (S2). The process in S2 is horizontal HB decoding.

After S2, it is determined whether all the plurality of code words CW including data of addresses of a plurality of pieces of target data TD have been correctly decoded (S3). In a case where all of the plurality of code words CW have been correctly decoded (S3: YES), the control circuit 13 outputs the plurality of pieces of target data TD (that is, a plurality of code words CW) of a plurality of physical addresses relating to the readout request to the memory controller 3 without adding parity data assuming that decoding of the plurality of code words CW including the plurality of pieces of target data have been successful. In this case, the memory controller 3 can output the plurality of pieces of target data TD received from the NAND memory 2 as is without delay.

In other words, the control circuit 13 provided at the NAND memory 2 determines whether or not to output the readout target data TD decoded through horizontal HB decoding using the parity data pbh on the basis of the bit error rate (BER). More specifically, when the control circuit 13 receives a readout command from the memory controller 3, in a case where the bit error rate (BER) is low, the control circuit 13 controls the decoder 15 so as to perform horizontal HB decoding using the parity data pbh on the readout target data TD relating to the readout command read out from the memory cell array unit 11, and outputs the decoded readout target data TD to the memory controller 3 in a case where horizontal HB decoding of the readout target data TD has been successful.

In a case where the bit error rate (BER) is not lower than predetermined percentage (S1: NO), or in a case where all of the plurality of code words CW including data of a plurality of addresses of a plurality of pieces of target data TD have not been correctly decoded (S3: NO), the control circuit 13 causes the second decoding process unit to execute vertical parity check, that is, vertical HB decoding starting from the product code frame of the sub-page data PCD using the product code data of 4 KB (S4). Through vertical parity check, for example, correction by erasure through XOR computation is performed. The process in S4 is hard bit (HB) decoding process of hard decision.

Note that in S4, iterative decoding may be executed such that after the vertical HB decoding is executed, horizontal HB decoding is further performed using data corrected through the vertical HB decoding, and if necessary, vertical HB decoding is further executed. For example, use of parity data based on a BCH code or a Reed-Solomon code in a vertical parity enables execution of iterative decoding.

After S4, the control circuit 13 determines whether all of the plurality of code words CW including data of addresses of the plurality of pieces of target data TD have been correctly decoded (S5). In a case where all of the plurality of code words CW have been correctly decoded (S5: YES), the control circuit 13 outputs the decoded user data of 4 KB to the memory controller 3 along with the plurality of code words CW of the decoded target data TD so as to execute CRC on the decoded data through vertical HB decoding. As a result, CRC is executed at the memory controller 3. Note that CRC may be executed at the control circuit 13.

In other words, in a case where the horizontal HB decoding of the readout target data (TD) has been failed, and in a case where the vertical HB decoding has been successful, the memory controller 3 executes CRC.

The processor 21 executes CRC on the user data received from the NAND memory 2 (S6) and determines whether the user data has passed CRC (S7). Here, CRC is performed in unit of sub-page data PCD.

As described above, in the present embodiment, in a case where the horizontal HB decoding has been failed when the bit error rate (BER) of the BER monitor 16 is low, and in a case where the bit error rate (BER) of the BER monitor 16 is not low, CRC is performed to prevent occurrence of error correction and prevent latency from becoming high. In other words, in a case where the bit error rate (BER) of the BER monitor 16 is low and the horizontal HB decoding has been successful, CRC is not performed.

In a case where it is determined that the user data has passed CRC (S7: YES), the processor 21 extracts a plurality of pieces of target data TD relating to random read and outputs the target data TD to the host 4.

As described above, the control circuit 13 controls the decoder 15 so as to perform vertical HB decoding using the parity bits pbv1 in the vertical direction in a case where the horizontal HB decoding of the readout target data TD has been failed (S3: NO). The control circuit 13 outputs the readout target data TD decoded through vertical HB decoding in a case where vertical HB decoding of the readout target data (TD) has been successful.

In a case where the plurality of code words CW have not been correctly decoded through hard decision decoding (S5: NO), the control circuit 13 outputs the product code frame including a plurality of pieces of target data to the memory controller 3, and the decoder 22a of the ECC circuit 22 executes horizontal SB decoding (S8). The process in S8 is soft bit (SB) decoding process of soft decision.

The processor 21, for example, reads out the code words CW relating to the plurality of pieces of target data a plurality of times, calculates probabilities of respective bits being “0” or “1” using the readout data and performs soft decision.

As described above, in a case where horizontal and vertical hard decision decoding of the readout target data TD has been failed (S5: NO), the processor 21 of the memory controller 3 controls the decoder 22a to perform horizontal SB decoding by the decoder 22a (S8).

The processor 21 determines whether the respective code words CW have been correctly decoded as a result of execution of the horizontal SB decoding (S9).

In a case where the horizontal SB decoding has been successful (S9: YES), the processor 21 executes process in S6 and S7.

In a case where the horizontal SB decoding has been failed (S9: NO), the processor 21 executes vertical SB decoding starting from the product code frame of the sub-page data PCD using the decoder 22a (S10). The process in S4 is soft bit (SB) decoding process of soft decision using XOR computation. The process of vertical SB decoding is performed in unit of sub-page data PCD. Note that in a case where the readout target data TD exists across four pieces of sub-page data PCD, the process of vertical SB decoding is performed in page unit.

In S10, vertical SB decoding is executed using the parity bit portion PBV in a longitudinal direction of the product code frame of the sub-page data PCD (for example, 4 KB).

Note that also in S10, iterative ECC as described above may be executed.

The processor 21 determines whether all of the code words CW including the target data TD have been correctly decoded as a result of execution of the vertical SB decoding (S11).

In a case where the vertical SB decoding has been successful (S11: YES), the processor 21 executes process in S6 and S7.

In a case where the vertical SB decoding has been failed (S11: NO) and in a case where the user data has not passed CRC (S7: NO), the processor 21 fails in readout of data and thus executes process determined in advance which is to be performed in a case where readout of data is failed.

As described above, in a case where the NAND memory 2 cannot perform error check and correct through hard decision (hard decision decoding) based on hard bits (HB), the memory controller 3 performs error check and correct through soft decision (soft decision decoding), so as to achieve improvement of a correction rate of error check and correct.

In other words, in a case where it is considered that an error correction rate of the page data Pd including the readout target data TD is low from the BER monitor 16, in a case where horizontal hard decision decoding of the code words CW of pages including the readout target data TD has been successful (S3: YES), the NAND memory 2 outputs the readout target data TD as is to the memory controller 3.

Further, in a case where horizontal hard decision decoding has been failed (S3: NO), and in a case where it is determined by the BER monitor 16 that the error correction rate of the page including the readout target data TD is not low (S1: NO), the memory controller 3 performs CRC to check that there is no error correction to prevent degradation of an error correction rate.

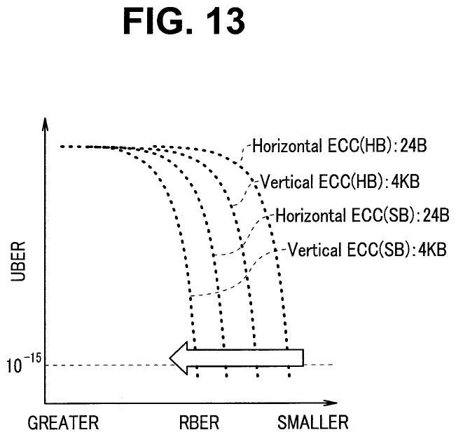

FIG. 13 is a schematic graph illustrating relationship between a detected raw bit error rate (RBER) and an uncorrectable bit error rate (UBER) in the hard decision decoding and the soft decision decoding described above.

All of a BER of horizontal hard decision decoding (horizontal ECC (HB)), a BER of vertical hard decision decoding (vertical ECC (HB)), a BER of horizontal soft decision decoding (horizontal ECC (SB)), and a BER of vertical soft decision decoding (vertical ECC (SB)) have uncorrectable bit error rates UBER which become greater as raw bit error rates RBER become greater.

Further, as raw bit error rates RBER become greater, uncorrectable bit error rates UBER become smaller in order of the BER of the vertical soft decision decoding (vertical ECC (SB)), the BER of the horizontal soft decision decoding (horizontal ECC (SB)), the BER of the vertical hard decision decoding (vertical ECC (HB)), and the BER of the horizontal hard decision decoding (horizontal ECC (HB)).

Thus, decoding is successful as quickly as possible by decoding being performed in the order illustrated in FIG. 11.

Here, a case where the number of planes of the NAND memory 2 is 16 will be described.

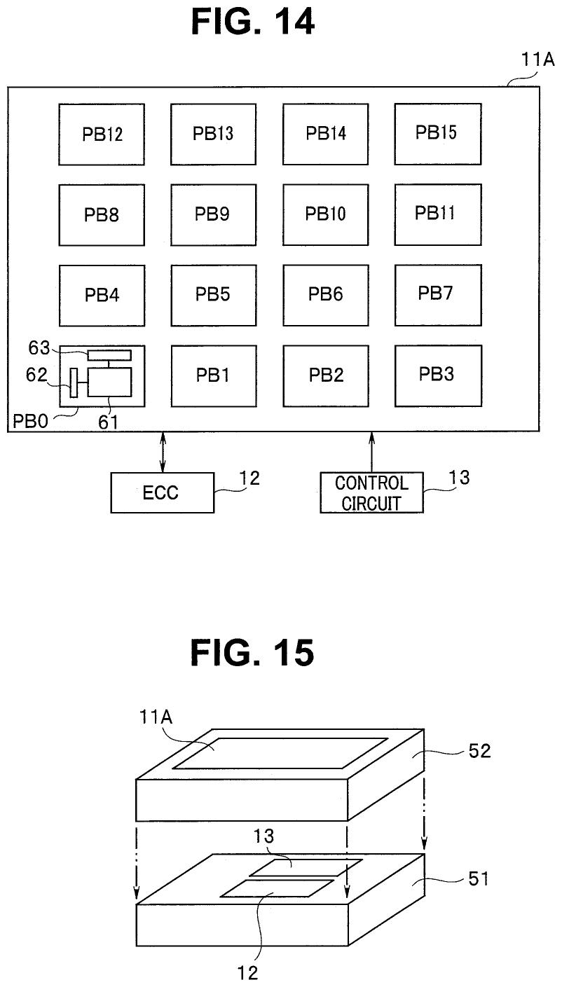

FIG. 14 is a block diagram illustrating a configuration of the NAND memory 2 where the memory cell array unit includes 16 planes. FIG. 15 is an assembly diagram illustrating the configuration of the NAND memory 2. The NAND memory 2 includes two semiconductor chips 51 and 52. The semiconductor chip 51 is a semiconductor device on which the ECC circuit 12 and the control circuit 13 are mounted. The semiconductor chip 52 is a semiconductor device on which the memory cell array unit 11A is mounted. The semiconductor chip 52 is laminated on an upper side of the semiconductor chip 51 and fixed with an adhesive. The semiconductor chip 51 is electrically connected to the semiconductor chip 52 through a ball bump, wire bonding, or the like.

Note that there may be a plurality of semiconductor chips 52. In this case, the plurality of semiconductor chips 52 are laminated on the upper side of the semiconductor chip 51 and respectively fixed with an adhesive.

The memory cell array unit 11A includes 16 planes PB (PB0, PB1, . . . , PB15). Each plane PB performs various kinds of operation described above in unit of blocks (not illustrated) including a plurality of memory cell transistors (not illustrated). More specifically, for example, each plane PB performs operation of writing data and operation of reading out data in and from part of memory cell transistors within a certain block, and performs operation of erasing data from all memory cell transistors within a certain block.

As illustrated in FIG. 14, the plane PB0 includes a memory cell array 61, a row decoder 62 and a sense amplifier module 63. The planes PB0 to PB15 have equivalent configurations unless otherwise described.

The memory cell array 61 includes a plurality of blocks BLK (BLK0, BLK1, . . . ). The respective blocks BLK are distinguished by block addresses which can identify the respective blocks. Note that the planes PB other than the plane PB0 also include blocks BLK corresponding to the same block addresses as the block addresses in the plane PB0. The blocks BLK to which the same block addresses are allocated among different planes PB are distinguished by plane addresses which can identify the respective planes. The block BLK includes a plurality of non-volatile memory cell transistors (not illustrated) associated with word lines and bit lines. The block BLK becomes, for example, a data erasure unit, and data within the same block BLK is collectively erased. Each block BLK includes a plurality of string units SU (SU0, SU1, . . . ). Each string unit SU includes a plurality of NAND strings NS. Note that the number of blocks within the memory cell array 61, the number of string units within one block BLK, and the number of NAND strings within one string unit SU can be set at any number.

The row decoder 62 selects the block BLK, or the like, on the basis of the block address in the address stored in a register which is not illustrated. Then, various kinds of voltages are transferred to the selected block BLK from the row decoder 62.

The sense amplifier module 63 reads out data by sensing a threshold voltage of the memory cell transistor upon readout of data. The sense amplifier module 63 transfers data to be written to the memory cell transistor via a bit line upon writing of data. Further, the sense amplifier module 63 receives a column address in the address from a register which is not illustrated and outputs data in a column based on the column address.

Here, a result of study by the applicant will be described regarding whether data of 64 B can be read out from 16 planes in a case where data of 4 KB is read out from each plane and data of 64 KB is read out from 16 planes, and in a case where a data readout period (tR) within the NAND memory 2A is 7.5 s, and data of 5.8 KB can be output per 7.5 μs as preconditions.

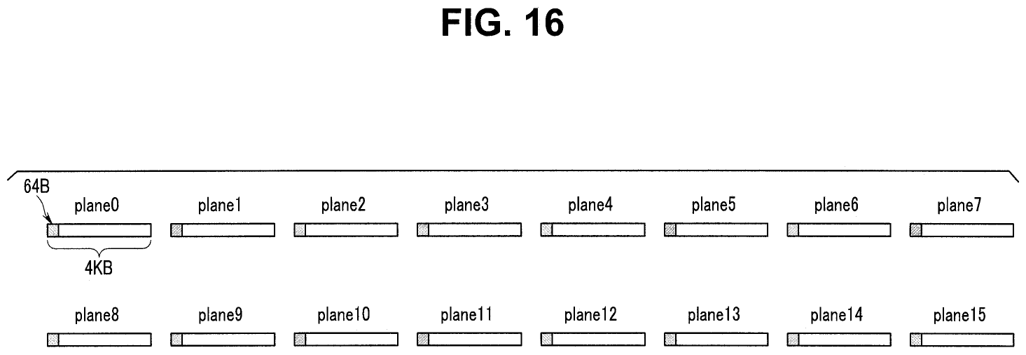

FIG. 16 is a diagram illustrating a case where one piece of data to be randomly read (64 B) exists in each plane of 16 planes. In other words, as illustrated in FIG. 16, each plane includes one piece of data of 64 B including the readout data.

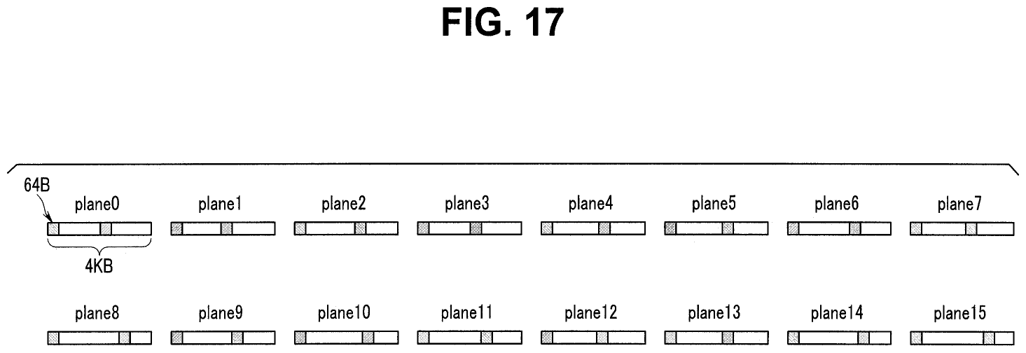

FIG. 17 is a diagram illustrating a case where two pieces of data to be randomly read (64 B) exists in each plane of 16 planes. As illustrated in FIG. 17, each plane includes two pieces of data of 64 B including the readout data.

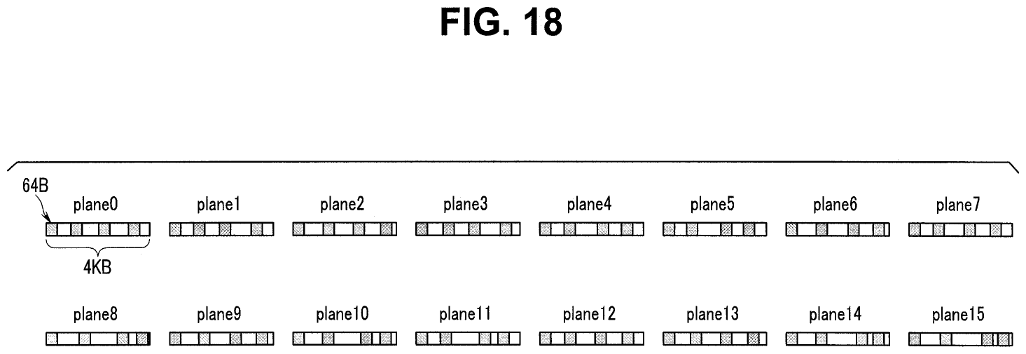

FIG. 18 is a diagram illustrating a case where four pieces of data to be randomly read (64 B) exists in each plane of 16 planes. As illustrated in FIG. 18, each plane includes four pieces of data of 64 B including the readout data.

Assuming that data output described above is possible, in a case of FIG. 18, if the code word length is 64 B, 90 frames can be read out, so that four pieces of data of 64 B can be read out from each plane. Note that in a case of FIG. 16, even if the code word length is 256 B, 23 frames can be read out, and in a case of FIG. 17, even if the code word length is 128 B, 32 frames can be read out.

Thus, the NAND memory 2 including 16 planes described above can be applied to the memory system as illustrated in FIG. 15 and FIG. 16 even in a case where the code word length is 64 B to 256 B.

Further, the memory system may include the memory controller 3 and a plurality of NAND memories 2.

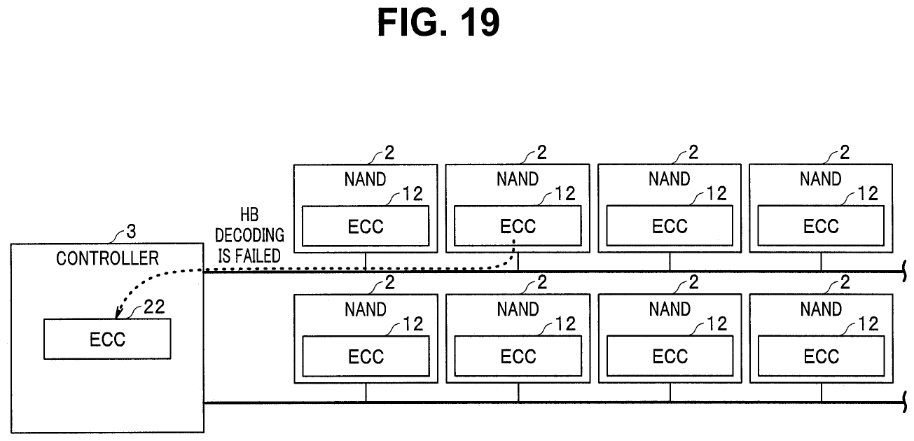

FIG. 19 is a diagram illustrating a configuration of the memory system including the memory controller 3 and a plurality of NAND memories 2.

The plurality of NAND memories 2 are connected to the memory controller 3 with two buses. Each NAND memory 2 includes the ECC circuit 22. When each NAND memory 2 receives a random read command from the memory controller 3, the NAND memory 2 can perform hard bit decoding described above and can output data for each 64 B to the memory controller 3.

As indicated with a dotted line in FIG. 19, if horizontal HB decoding and vertical HB decoding fail at the NAND memory 2, soft bit decoding is performed at the ECC circuit 22 of the memory controller 3.

Also in the memory system employing the configuration as illustrated in FIG. 19, in a case where the code word length is set at 64 B and data is read out from all the 16 planes PB or 16 NAND memories 2, the number of times that readout can be performed for one second (IOPS (input output per second)) becomes 16 times. It is therefore possible to apply the configuration of the above-described embodiment also to the memory system as illustrated in FIG. 19.

Further, in the above-described embodiment, the NAND memory 2 determines whether horizontal and vertical hard decision decoding has been successful or failed. Thus, the control circuit 13 stores the determination result, and thus, if the control circuit 13 receives an inquiry command for making an inquiry as to a correction error status from the memory controller 3, the control circuit 13 can output the correction status to the memory controller 3 using part of the data input/output lines DQ0 to DQ7. In other words, the control circuit 13 may be able to output information regarding successes and failures of the horizontal HB decoding and the vertical HB decoding.

For example, there is a data input/output line which is not used when a data readout command is executed. The control circuit 13 can output the correction status information to the memory controller 3 using such a data input/output line which is not used. For example, in a case where horizontal ECC correction has been successful, the control circuit 13 makes output of the data input/output line DQ0 low, and in a case where the horizontal ECC correction has been failed, makes the output of the data input/output line DQ0 high. In a case where vertical ECC correction has been successful, the control circuit 13 makes output of the data input/output line DQ1 low, and in a case where the vertical ECC correction has been failed, makes the output of the data input/output line DQ1 high.

Further, in a case where CRC is caused to be executed at the NAND memory 2, the control circuit 13 makes output of the data input/output line DQ2 low in a case where CRC correction has been successful and makes the output of the data input/output line DQ2 high in a case where the CRC correction has been failed.

Thus, the memory controller 3 can obtain information regarding a state of the ECC correction (success or failure) at the NAND memory 2.

Note that while in the above-described embodiment, the BER monitor 16 creates histogram when random read is performed, the BER monitor 16 may generate histogram when so-called read patrol, or the like, is performed.

As described above, according to the above-described embodiment, it is possible to provide a memory system, a semiconductor storage device and a method for reading out data which enable random read without reducing a code rate of data.

Correction capability of the memory system 1 in the above-described embodiment is higher than correction capability of a memory system which performs ECC correction at the memory controller 3 without using a product code.

For example, in a case where a memory system A is assumed where an ECC frame length is 64 B, a code rate is 0.89, and BCH encoding (correction of bits equal to or less than four bits) is performed for each of data of 64 B at the memory controller 3, according to simulation performed by the applicant, correction capability of the memory system A is 0.04% in terms of 4 KB.

In contrast, in a case of a memory system B as described in the above-described embodiment where the ECC frame length is 4 KB, and BCH encoding (correction of bits equal to or less than four bits) is performed for each of data of 48 B with a product code frame having the code word CW length of 48 B, according to the simulation performed by the applicant, correction capability of the memory system B is 0.22% in terms of 4 KB. The correction capability of the memory system B according to the present embodiment is 5.5 times of the correction capability of the memory system A.

Further, according to the simulation performed by the applicant, execution throughput of the memory system B according to the present embodiment is 24 times of execution throughput of the above-described memory system A.

Further, according to the simulation performed by the applicant, current efficiency of the memory system B according to the present embodiment is 0.73 mA/1000 MiBPS, and current efficiency of the above-described memory system A is 7.5 mA/1000 MiBPS. The current efficiency of the memory system B according to the present embodiment is 1/10 of the current efficiency of the memory system A.

Further, according to the simulation performed by the applicant, a circuit scale (decoding portion) of the memory system B according to the present embodiment is 40 K Unit (where 1 Unit corresponds to two-input NAND), and a circuit scale (decoding portion) of the above-described memory system A is 63 KU. The circuit scale (decoding portion) of the memory system B according to the present embodiment is 0.63 of the circuit scale (decoding portion) of the memory system A.

### (Modification 1)

While in the above-described embodiment, a memory system which can perform random read using the NAND memory 2 is disclosed, the memory system may be able to switch an operation mode between an operation mode in which data is read out for each piece of page data or sub-page data as in the related art and an operation mode in which random read is performed as in the above-described embodiment.

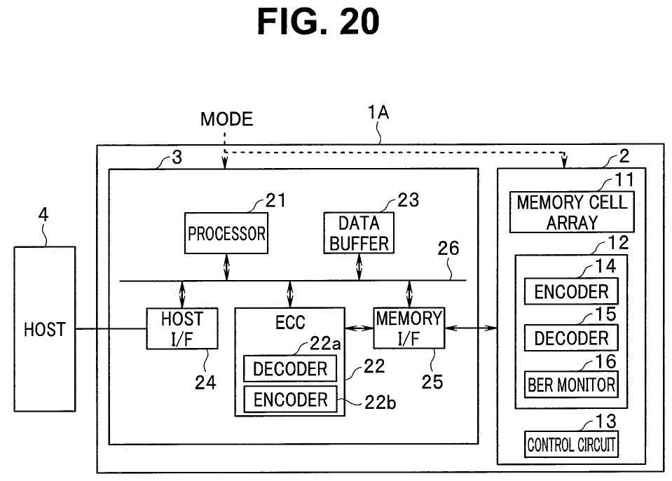

FIG. 20 is a block diagram illustrating a configuration of a memory system according to modification 1. In FIG. 20, the same reference numerals will be assigned to components which are the same as the components in FIG. 1, description will be omitted, and only components different from the components in FIG. 1 will be described.

An ECC circuit of the memory controller 3 includes an encoder 22b. An operation mode signal MODE can be externally input to the memory system 1A. The operation mode signal MODE is set to be high or low by bonding switching on the semiconductor device and is provided to the NAND memory 2 and the memory controller 3.

Note that the operation mode signal MODE may be provided to the memory system 1A as a setting signal from outside.

In a case where the operation mode signal MODE is high, the memory system 1A operates as a system which can perform random read by executing operation similar to the operation in the above-described embodiment without using the encoder 22b of the ECC circuit 22.

In a case where the operation mode signal MODE is low, in the memory system 1A, the encoder 22b of the ECC circuit 22 is used to encode page data, and a decoder 22a also decodes the page data encoded by the encoder 22b. In a case where the operation mode signal MODE is low, further, the ECC circuit 12 of the NAND memory 2 is not used.

In a case where the operation mode signal MODE is low, the memory system 1A writes and reads out data in page unit as a normal NAND memory.

In a case where the operation mode signal MODE is high, the memory system 1A writes data in page unit and randomly reads out data without using the encoder 22b of the memory controller 3.

Note that in a case where the memory cell array 11a is a multiple-valued cell memory, for example, a QLC (quad-level cell) memory of 4 bit/cell, the bit error rate (BER) of the QLC memory is high, and thus, the memory cell array 11a may be used as a TLC (triple-level cell) memory so as to improve random read performance by lowering the bit error rate (BER) although data write speed becomes lower.

In other words, in a case where a memory system which can perform random read is configured using a multiple-valued non-volatile memory, random read performance can be improved by writing data in the non-volatile memory through low-speed writing which is so-called high-reliability writing.

While in the above-described embodiment, the NAND memory 2 which is a non-volatile memory can lower the bit error rate (BER) by using an SLC (single-level cell), a cost advantage of the memory system can be made larger by using a TLC memory or a QLC memory.

### (Modification 2)

While in the above-described embodiment, target data TD in one piece of page data Pd in one word line WL in one block BLK is randomly read, in the present modification, a plurality of pieces of target data TD in a plurality of blocks BLK or a plurality of pieces of target data TD in a plurality of word lines WL within one block BLK are randomly read.

For example, by the BER monitor 16 creating histogram from data of the number of corrected bits for each page buffer using the page buffer for each block BLK, a plurality of pieces of target data TD within a plurality of blocks BLK can be read out at the same time.

Further, by causing a plurality of word lines WL including a plurality of pieces of target data TD within one block BLK to sequentially operate and decoding a code word CW including the target data TD from each word line WL, the plurality of pieces of target data TD within one block BLK can be read out together.

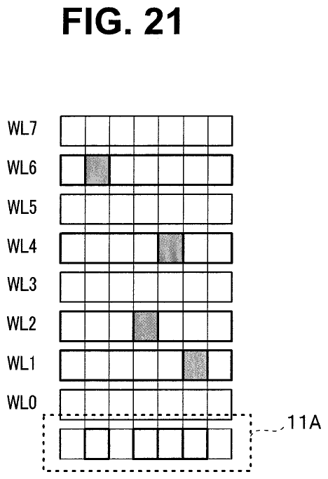

FIG. 21 is a diagram for explaining a case where a plurality of pieces of target data TD in a plurality of word lines WL are randomly read. A blacked out portion indicates code words CW including the target data TD.

In a case of FIG. 21, data in four word lines WL including the target data TD is read out at the same time and stored in a page buffer portion 11A including four page buffers indicated with a dotted line. The BER monitor 16 generates histogram of the number of corrected bits in the BER monitor region PB in each piece of page data PD, and decoding process of the target data TD for each page is executed.

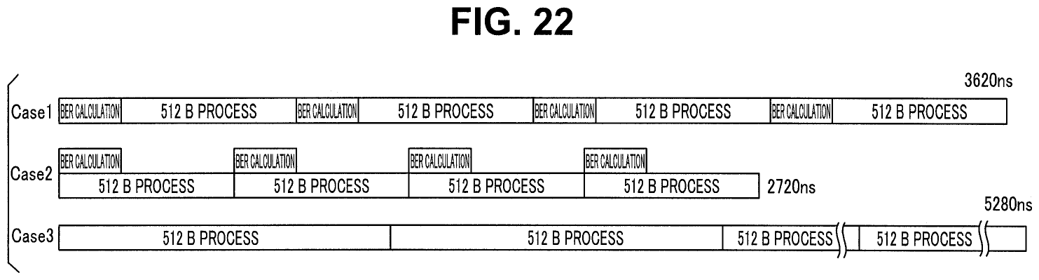

FIG. 22 is a graph for explaining timings for calculating histogram concerning four word lines WL at the BER monitor 16. FIG. 22 is a diagram illustrating timings in a case where data of 12.5% (2 KB) in one piece of page data (approximately 16 KB) is read out. FIG. 22 is a timing chart of case 1 where calculation of histogram and random read are sequentially performed for four word lines WL, case 2 where calculation of histogram and random read are performed in parallel for each word line WL, and case 3 where decoding is performed at the memory controller 3, and data of 2 KB is read out.

In case 1, histogram of data of the number of corrected bits is calculated using a plurality of code words CW (24 B) in the BER monitor region PB in the page data Pd for each word line WL and, then, data of 2 KB is read out. In simulation calculation by the applicant under predetermined conditions, it takes 3620 ns (nanoseconds) to read out data of 2 KB.

In case 2, histogram of data of the number of corrected bits is calculated using a plurality of code words CW (24 B) in the BER monitor region PB in the page data Pd for each word line WL in parallel to readout of data of 2 KB. In simulation calculation by the applicant under predetermined conditions, it takes 2720 ns (nanoseconds) to read out data of 2 KB.

In case 3, in simulation calculation by the applicant under predetermined conditions, it takes 5160 ns (nanoseconds) to read out data of 2 KB for four word lines WL.

Thus, the present modification 2 provides effects equivalent to the effects of the embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory system comprising:
a non-volatile memory;
a controller configured to control write and readout of data in and from the non-volatile memory;
an encoder provided in the non-volatile memory and configured to convert first data to be written in the non-volatile memory into second data including a plurality of pieces of unit data generated by dividing the first data into the unit data having a predetermined number of bits, generate first parity data of the second data for error check and correct and second parity data of the second data different from the first parity data for each piece of the unit data, and perform encoding of the first data;
a first decoder provided in the non-volatile memory and configured to perform decoding of readout data read out from the non-volatile memory; and
a control circuit provided in the non-volatile memory and configured to control the first decoder to perform first decoding using the first parity data on readout target data read out from the non-volatile memory when a readout command is received from the controller, and output the decoded readout target data to the controller when the first decoding of the readout target data is successful.

2. The memory system according to claim 1, wherein the first decoding is hard decision decoding.

3. The memory system according to claim 1, wherein
the encoder performs the encoding through BCH encoding in which bits equal to or less than four bits are corrected, and
the first decoder performs the decoding using a direct method.

4. The memory system according to claim 1, wherein
the non-volatile memory comprises a bit error rate monitor configured to calculate a bit error rate based on a number of corrected bits for each piece of the unit data and monitor the bit error rate, after the first decoder decodes data in part of a storage region of the non-volatile memory including the readout target data for each piece of the unit data, and
the control circuit determines whether or not to output the readout target data decoded through the first decoding using the first parity data on a basis of the bit error rate.

5. The memory system according to claim 4, wherein the part of the storage region is part of data which is a unit of readout of data from the non-volatile memory.

6. The memory system according to claim 1, wherein the control circuit controls the first decoder to perform second decoding using the second parity data when the first decoding of the readout target data is failed and outputs the readout target data decoded through the second decoding when the second decoding of the readout target data is successful.

7. The memory system according to claim 6, wherein the second decoding is hard decision decoding.

8. The memory system according to claim 6, wherein
the controller comprises a second decoder configured to perform soft decision decoding, and
the controller controls the second decoder to perform the soft decision decoding when the first decoding and the second decoding of the readout target data are failed.

9. The memory system according to claim 6, wherein the controller performs cyclic redundancy check when the first decoding of the readout target data is failed and the second decoding is successful.

10. The memory system according to claim 1, wherein
the first decoder comprises an error determination circuit configured to determine a number of errors, a first search circuit configured to search an error bit location in a first number of errors, and a second search circuit configured to search an error bit location in a second number of errors different from the first number of errors, and
the first search circuit and the second search circuit are controlled so that the first search circuit operates in a case where the number of errors determined by the error determination circuit is the first number of errors, and the second search circuit operates in a case where the number of errors determined by the error determination circuit is the second number of errors.

11. The memory system according to claim 10, wherein the first search circuit and the second search circuit are controlled so that neither the first search circuit nor the second search circuit operates in a case where the number of errors determined by the error determination circuit is 0.

12. The memory system according to claim 1, wherein the non-volatile memory is a NAND flash memory.

13. The memory system according to claim 6, wherein the control circuit is capable of outputting information regarding successes and failures of the first decoding and the second decoding.

14. A semiconductor storage device having a non-volatile storage region, the semiconductor storage device comprising:
an encoder configured to convert first data into second data including a plurality of pieces of unit data generated by dividing the first data into the unit data having a predetermined number of bits, generate first parity data of the second data for error check and correct and second parity data of the second data different from the first parity data for each piece of the unit data, and perform encoding of the first data;
a decoder configured to perform decoding of readout data read out from the non-volatile storage region; and
a control circuit configured to control the decoder to perform first decoding using the first parity data on readout target data read out from the non-volatile storage region when a readout command is received and output the decoded readout target data when the first decoding of the readout target data is successful.

15. The semiconductor storage device according to claim 14, wherein
the encoder performs the encoding through BCH encoding in which bits equal to or less than four bits are corrected, and
the decoder performs the decoding using a direct method.

16. The semiconductor storage device according to claim 14, wherein the control circuit controls the decoder to perform second decoding using the second parity data when the first decoding of the readout target data is failed and output the readout target data decoded through the second decoding when the second decoding of the readout target data is successful.

17. The semiconductor storage device according to claim 14, wherein the control circuit can output information regarding successes and failures of the first decoding and the second decoding.

18. The semiconductor storage device according to claim 14, wherein
the decoder comprises an error determination circuit configured to determine a number of errors, a first search circuit configured to search an error bit location in a first number of errors, and a second search circuit configured to search an error bit location in a second number of errors different from the first number of errors, and
the first search circuit and the second search circuit are controlled so that the first search circuit operates in a case where the number of errors determined by the error determination circuit is the first number of errors, the second search circuit operates in a case where the number of errors determined by the error determination circuit is the second number of errors, and neither the first search circuit nor the second search circuit operates in a case where the number of errors determined by the error determination circuit is 0.

19. A method for reading out data from a non-volatile memory comprising:
converting first data to be written in the non-volatile memory into second data including a plurality of pieces of unit data generated by dividing the first data into the unit data having a predetermined number of bits, generating first parity data of the second data for error check and correct and second parity data of the second data different from the first parity data for each piece of the unit data, and performing encoding of the first data in the non-volatile memory;
performing decoding of readout data read out from the non-volatile memory in the non-volatile memory; and
performing first decoding using the first parity data on readout target data read out from the non-volatile memory when a readout command is received and outputting the decoded readout target data when the first decoding of the readout target data is successful in the non-volatile memory.

20. The method for reading out data according to claim 19, wherein the first decoding is hard decision decoding.
